(19) United States
(12) Patent Application Publication
(10) Pub. No.: US 2018/0219051 A1
(43) Pub. Date: Aug. 2, 2018

(54) COLOR FILTER ARRAY ON DIRECTLY PATTERNED AMOLED DISPLAYS AND METHOD OF FABRICATION

(71) Applicant: eMagin Corporation, Hopewell Junction, NY (US)

(72) Inventors: Amalkumar P. GHOSH, Hopewell Junction, NY (US); Evan P. DONOGHUE, Hopewell Junction, NY (US); Ilyas I. KHAYRULLIN, Hopewell Junction, NY (US); Qi WANG, Hopewell Junction, NY (US); Tariq ALI, Hopewell Junction, NY (US)

(21) Appl. No.: 15/882,364

(22) Filed: Jan. 29, 2018

Related U.S. Application Data
(60) Provisional application No. 62/451,747, filed on Jan. 29, 2017.

(51) Int. Cl. H01L 27/32; H01L 51/56; H01L 21/66

(52) U.S. Cl. CPC H01L 27/3211; H01L 51/56; H01L 2251/558; H01L 27/322; H01L 22/20

(57) ABSTRACT

A method of fabricating an Organic Light Emitting Diode (OLED) sub-pixel including providing an insulating structure upon which at least one color light emitter is directly patterned between an anode and cathode pair, the anode and cathode pair when energized being configured to cause the at least one color light emitter to radiate visible light in an emission spectrum, and patterning a color filter above the anode and cathode pair and over the corresponding at least one color light emitter. The radiated visible light in the emission spectrum from the at least one color light emitter is configured to pass through the color filter and radiate visible light in a filtered spectrum, the radiated visible light in the filtered spectrum being narrower in wavelength than radiated visible light in the emission spectrum.

### CROSS-REFERENCE TO RELATED APPLICATIONS

This application claims the benefit of U.S. Provisional Application No. 62/451,747 filed Jan. 29, 2017, which is incorporated herein by reference.

### BACKGROUND

### 1. Field of the Invention

The present invention relates to light emitting devices. In particular, the present invention relates to a filter design and filter patterning method for directly patterned organic light emitting diode (“OLED”) devices.

### 2. Description of the Related Art

Currently, OLED display technology utilizes two general approaches to deliver color images. The first approach utilizes a color display that produces a white light emission from a common white light OLED stack. The white light emission is filtered through three single color filter layers residing on three adjacent sub-pixels to produce red, green and blue colors (alternatively referred to herein as RGB colors). However, the three RBG color filters residing on the corresponding three adjacent sub-pixels filter all but one wavelength range from the white emissive OLED, and thereby significantly attenuate the emissive intensity of each OLED stack.

The second approach addresses the reduction in intensity of the OLED by providing a color display that includes three entirely different color OLED stacks residing on three adjacent individually driven sub-pixels to produce red, green, and blue (RGB) color emissions due to the distinct configuration of organic layers within the individually designed OLED stacks.

Therefore, a need exists to color correct individually driven red, green, and blue color emitters to tune each required RBG color emitter to expand the color gamut of each sub-pixel of the plurality of sub-pixels that make up the OLED display, particularly since generating deeply saturated colors is currently limited by RGB OLED material development

### SUMMARY

It should be appreciated that this Summary is provided to introduce a selection of concepts in a simplified form that are further described below in the Detailed Description. This Summary is not intended to be used to limit the scope of the claimed subject matter.

In one embodiment disclosed herein, a method of fabricating an Organic Light Emitting Diode (OLED) sub-pixel including providing an insulating structure upon which at least one color light emitter is directly patterned between an anode and cathode pair, the anode and cathode pair when energized being configured to cause the at least one color light emitter to radiate visible light in an emission spectrum; and patterning a color filter above the anode and cathode pair and over the corresponding at least one color light emitter. The radiated visible light in the emission spectrum from the at least one color light emitter is configured to pass through the color filter and radiate visible light in a filtered spectrum, the radiated visible light in the filtered spectrum being narrower in wavelength than radiated visible light in the emission spectrum.

The embodiment further includes fabricating the OLED sub-pixel to include applying an adhesive layer directly over the color filter above the anode and cathode pair and over the corresponding at least one color light emitter, and over second and third anode and cathode pairs of the OLED sub-pixel, wherein the second and third anode and cathode pairs are void of any patterned color filter.

The embodiment further includes fabricating the OLED sub-pixel to including providing a plurality of color light emitters each disposed between corresponding anode and cathode pairs, each anode and cathode pair when energized being configured to cause a corresponding color light emitter to radiate visible light a discrete emission spectrum. The radiated visible light particular in the emission spectrum from each of the plurality of color light emitters is configured to pass through a discrete color filter and radiate visible light in a discrete filtered spectrum.

The embodiment further includes fabricating the OLED sub-pixel where each the plurality of color light emitters includes one of a substantially red emission spectrum emitter centered on a substantially red wavelength, a substantially green emission spectrum emitter centered on a substantially green wavelength, or a substantially blue emission spectrum emitter centered on a substantially blue wavelength. Furthermore, each corresponding color filter for the plurality of color light emitters includes one of a red filtered spectrum filter centered on the substantially red wavelength, a green filtered spectrum color filter centered on the substantially green wavelength, and a blue filtered spectrum color filter centered on the substantially blue wavelength.

The embodiment further includes fabricating the OLED sub-pixel where patterning the color filter above the anode and cathode pair and over the corresponding at least one color light emitter further includes patterning one of the red filtered spectrum filter, the green filtered spectrum filter, or the blue filtered spectrum filter over a first of the plurality of color light emitters disposed between a first anode and cathode pair, and patterning another of the red filtered spectrum filter, the green filtered spectrum filter, or the blue filtered spectrum filter over a second of the plurality of color light emitters disposed between a second anode and cathode pair.

The embodiment further includes fabricating the OLED sub-pixel where the one of the red filtered spectrum filter, the green filtered spectrum filter, or the blue filtered spectrum filter has a first color filter thickness, and where the another of the red filtered spectrum filter, the green filtered spectrum filter, or the blue filtered spectrum filter has a second color filter thickness. Where the first color filter thickness being substantially different than the second color filter thickness.

The embodiment further includes fabricating the OLED sub-pixel further including applying an adhesive layer directly over the one of the red filtered spectrum filter, the green filtered spectrum filter, or the blue filtered spectrum filter has a first color filter thickness, the another of the red filtered spectrum filter, the green filtered spectrum filter, or the blue filtered spectrum filter has a second color filter thickness, and a third anode and cathode pair, wherein the third anode and cathode pair is void of any color filter.

The embodiment further includes fabricating the OLED sub-pixel where patterning the color filter above the anode and cathode pair and over the corresponding at least one color light emitter further includes patterning the red filtered spectrum filter over the substantially red emission spectrum emitter, patterning the green filtered spectrum filter over the substantially green emission spectrum emitter, and patterning the blue filtered spectrum filter over the substantially blue emission spectrum emitter.

The embodiment further includes fabricating the OLED sub-pixel where at least two of the red filtered spectrum filter, the green filtered spectrum filter, and the blue filtered spectrum filter includes substantially different thicknesses.

The embodiment further includes fabricating the OLED sub-pixel further including applying an adhesive layer directly over the red filtered spectrum color filter, the green filtered spectrum color filter, and the blue filtered spectrum color filter, adhering a transparent protective layer via the adhesive layer. Where the adhesive layer accommodates for differences in thicknesses of the at least two of the red filtered spectrum color filter, the green filtered spectrum color and the blue filtered spectrum color filter with respect to adjacent anode and cathode pairs.

In another embodiment disclosed herein, an Organic Light Emitting Diode (OLED) device includes a plurality of sub-pixels arranged in an array, each of the plurality of sub-pixels including an insulating structure upon which a plurality of color light emitters are directly patterned between corresponding anode and cathode pairs, the anode and cathode pairs when energized being configured to cause each corresponding color light emitter to radiate visible light in one of a red, green or blue emissive spectrum, and at least one color filter disposed above at least one of the anode and cathode pairs and over at least one of the corresponding plurality of color light emitters, wherein the radiated visible in one of the red, green or blue emissive spectrum from the plurality of color light emitters is configured to pass through the at least one color filter and radiate visible light in a corresponding narrowed red, green or blue filtered spectrum. The OLED device further including a controller configured to address each of plurality of sub-pixels in the array and configured to control the energizing of each anode and cathode pair to cause a corresponding color light emitter to radiate visible light in one of a red, green or blue emissive spectrum.

The embodiment further includes an adhesive layer disposed over the at least one color filter, and a transparent protective layer disposed over the plurality of sub-pixels arranged in the array, wherein the adhesive layer accommodates for differences in total thicknesses of sub-pixels with respect to adjacent anode and cathode pairs between the anode and cathode pairs and the transparent protective layer.

The embodiment further includes at least two color filters disposed above at least two corresponding anode and cathode pairs and over at least two corresponding plurality of color light emitters, where the radiated emissive spectrum from each of the at least two corresponding plurality of color light emitters is configured to pass through the corresponding at least two color filters and radiate visible light in a corresponding narrowed red, green or blue filtered spectrum.

The embodiment further includes the OLED device where at least two color filters includes substantially different thicknesses.

The embodiment further includes the OLED device further including a red color filter disposed above a first corresponding anode and cathode pair and over a red emission spectrum color light emitter configured to emit a corresponding narrowed red filtered spectrum, a green color filter disposed above a second corresponding anode and cathode pair and over a green emission spectrum color light emitter configured to emit a corresponding narrowed green filtered spectrum, and a blue color filter disposed above a third corresponding anode and cathode pair and over a blue emission spectrum color light emitter configured to emit a corresponding narrowed blue filtered spectrum.

The embodiment further includes the OLED device where at least two of the red color filter, the green color filter, and the blue color filter includes substantially different thicknesses.

The embodiment further includes the OLED device where each of the plurality of color light emitters pixels is less than or equal to 15 microns in size, and wherein the at least one color filter includes a fluorescing quantum dot material.

In another embodiment disclosed herein, a method of fabricating an Organic Light Emitting Diode (OLED) sub-pixel includes providing an insulating structure upon which at least one color light emitter is directly patterned between an anode and cathode pair, energizing the anode and cathode pair to cause the color light emitter to radiate visible light in the emission spectrum centered in one of a substantially red, substantially green or substantially blue wavelength, measuring a wavelength of the radiated visible light in the emission spectrum of the at least one color light emitter. The method further includes determining a color filter thickness based on the measured wavelength of the radiated visible light in the emission spectrum being compared to a target emission spectrum, and patterning a color filter having the color filter thickness above the anode and cathode pair and over the at least one color light emitter. The color filter is configured to cause the visible light in the emission spectrum to radiate visible light in a filtered spectrum, the filtered spectrum being narrower in wavelength than the emission spectrum and being calibrated to a predetermined color gamut value based on the color filter thickness.

The embodiment further includes fabricating the OLED sub-pixel to further include measuring a second wavelength of radiated visible light in a second emission spectrum of a second color light emitter, determining a second color filter thickness based on the measured second wavelength of the radiated visible light in the second emission spectrum of the second color light emitter being compared to a second target emission spectrum, and patterning a second color filter having a second color filter thickness above a second anode and cathode pair and over the second color light emitter. The second color filter is configured to cause the visible light in the emission spectrum of the second color light emitter to radiate visible light in a second filtered spectrum, the second filtered spectrum being narrower in wavelength than the emission spectrum of the second color light emitter and being calibrated to a second predetermined color gamut value based on the second color filter thickness.

The embodiment further includes the method of fabricating the OLED sub-pixel further including measuring a third wavelength of radiated visible light in third emission spectrum of a third color light emitter, determining a third color filter thickness based on the measured third wavelength of the radiated visible light in the third emission spectrum of the third color light emitter being compared to a third target emission spectrum, and patterning a third color filter having a third color filter thickness above a third anode and cathode pair and over the third color light emitter. The third color filter is configured to cause the visible light in the emission spectrum of the third color light emitter to radiate visible light in a third filtered spectrum, the third filtered spectrum being narrower in wavelength than the emission spectrum of the third color light emitter and being calibrated to a third predetermined color gamut value based on the third color filter thickness.

### BRIEF DESCRIPTION OF THE SEVERAL VIEWS OF THE DRAWINGS

The embodiments of the invention will be better understood from the following detailed description with reference to the drawings, which are not necessarily drawing to scale and in which:

FIGS. 1A-1C illustrate a fabrication sequence of a directly patterned OLED display;

FIG. 1A illustrates a first step in fabrication of a the directly patterned OLED display where the anodes are patterned upon a silicon backplane;

FIG. 1B illustrates a second step in fabrication of a the directly patterned OLED display where a hole injection layer, a hole transport layer and red, green and blue emissive layers are patterned upon the partial build-up of FIG. 1A;

FIG. 1C illustrates a third step in fabrication of a the directly patterned OLED display where an electron transport layer, a cathode and a thin film encapsulation are patterned upon the partial build-up of FIG. 1B;

FIGS. 2A-2D illustrates a first embodiment of the OLED sub-pixel of the directly patterned OLED display;

FIG. 2A illustrates patterning a red, green and blue color filter upon the partial build-up of FIG. 1C;

FIG. 2B illustrates patterning a transparent organic layer on the partial build-up of FIG. 2A;

FIG. 2C illustrates patterning an adhesive layer on the partial build-up of FIG. 2B;

FIG. 2D illustrates adjoining a cover glass layer on the partial build-up of FIG. 2C, thereby illustrating a completed sub-pixel of the first embodiment;

FIGS. 3A-3D illustrates a second embodiment of the OLED sub-pixel of the directly patterned OLED display;

FIG. 3A illustrates patterning a red, green and blue color filter upon the partial build-up of FIG. 1C;

FIG. 3B illustrates patterning a transparent organic layer on the partial build-up of FIG. 3A;

FIG. 3C illustrates patterning an adhesive layer on the partial build-up of FIG. 3B;

FIG. 3D illustrates adjoining a cover glass layer on the partial build-up of FIG. 3C, thereby illustrating a completed sub-pixel of the second embodiment;

FIG. 4 illustrates a color gamut calculation using NTSC 1987 depicting an uncorrected/unfiltered directly patterned OLED display;

FIG. 5 illustrates a color gamut calculation using NTSC 1987 depicting an corrected/filtered directly patterned OLED display;

FIG. 6A illustrates a wavelength vs. normalized intensity chart for the color blue depicting spectra with and without a blue color filter;

FIG. 6B illustrates a wavelength vs. normalized intensity chart for the color green depicting spectra with and without a green color filter;

FIG. 6C illustrates a wavelength vs. normalized intensity chart for the color red depicting spectra with and without a blue red filter;

FIG. 6D illustrates a table showing a standard DP (direct pattern) OLED 1931 CIE-x and 1931 CIE-y values for unfiltered red, green and blue emissions;

FIG. 6E illustrates a table showing an enhanced gamut DP (direct pattern) OLED 1931 CIE-x and 1931 CIE-y values for filtered red, green and blue emissions;

FIG. 7 illustrates a logic flow diagram of a first embodiment of a method of fabrication an OLED sub-pixel;

FIG. 8 illustrates a logic flow diagram of a second embodiment of a method of fabrication an OLED sub-pixel; and

FIG. 9 illustrates a computer system according to an exemplary embodiment configured to drive an OLED array using the directly patterned OLED display of the first and second embodiments depicted in FIGS. 1-3D.

### DETAILED DESCRIPTION

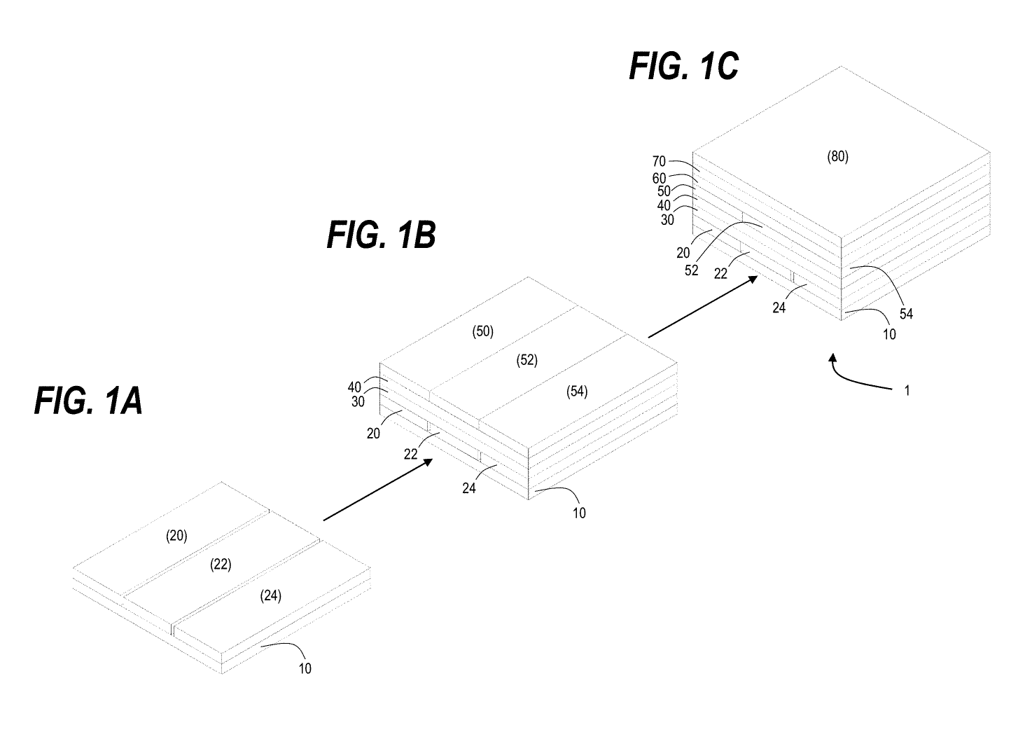

FIGS. 1A-1C illustrate a fabrication sequence of a directly patterned OLED display. An OLED device typically may include a stack of thin layers, or films, formed on a substrate backplane. A variety of technologies may be used to fabricate OLED display backplanes including but not limited to single crystal silicon and polysilicon wafers, glass backplanes with layers of transparent conducting films, and flexible organic or inorganic backplanes.

The thin layers or films of the OLED device may be formed by evaporation, spin casting, other appropriate polymer film-forming techniques, or chemical self-assembly. Thicknesses typically may range from one monolayer to a few thousand angstroms.

In the OLED stack, a light-emitting layer of a luminescent organic solid, as well as adjacent semiconductor layers, is sandwiched between a cathode and an anode. In a typical OLED, either the cathode or the anode is transparent. The light-emitting layer may be selected from any of a multitude of fluorescent organic solids. Any of the layers, and particularly the light-emitting layer, may consist of multiple sub-layers or a single uniform layer.

Protection of OLED stack against oxygen and moisture may be achieved by encapsulation of the device. The encapsulation may be obtained by means of a single thin-film layer situated on the substrate, surrounding the OLED.

FIG. 1A illustrates a first step in fabrication of a directly patterned OLED display of the later described first and second embodiments where each of the color specific (red, green and blue, or “RGB”) electrode layers 20, 22 and 24 are patterned upon a silicon backplane 10 such that each RGB color specific electrode layer is electrically insulated from adjacent color specific electrode layers. For example, a red electrode layer 20 may correspond to the red OLED stack, a green electrode layer 22 may correspond to the green OLED stack, and a blue electrode layer 24 may correspond to the blue OLED stack. Each of these electrode layers may be substituted for another color or may ordered in a different manner as presented herein. The presentation of this particular order is merely for representative purposes and consistency for the remainder of this disclosure. RGB electrode layers 20, 22 and 24 may be an anode or a cathode, and may be transparent, reflective or opaque.

FIG. 1B illustrates a second step in fabrication of a the directly patterned OLED display where a hole injection layer 30, a hole transport layer 40, and red 50, green 52 and blue 54 emissive layers are patterned upon the partial build-up of FIG. 1A. Red emissive layer 50, green emissive layer 52 and blue emissive layer 54 each comprise discrete color wavelength emitters that have a narrower wavelength than a broad spectrum white light emitter. Each of the color (RGB) emissive layers' color corresponds to the RGB electrode layers 20, 22 and 24 that lies beneath it for the purposes of this disclosure. Each of the RGB emissive layers 50, 52 and 54 may comprise phosphorescent or fluorescent organic solids, and/or quantum dot materials. The RGB emissive layers 50, 52 and 54 may be configured in a tandem OLED structure where plural light-emitting units are stacked in series between the corresponding electrode layers and an electron injection layer.

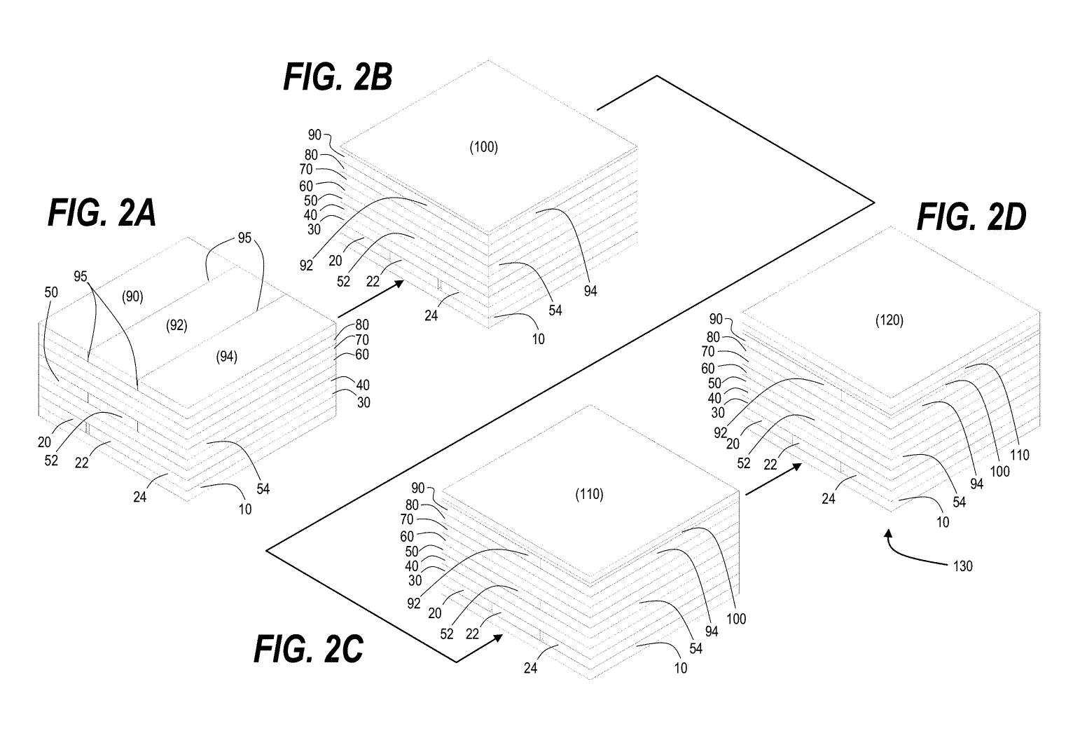

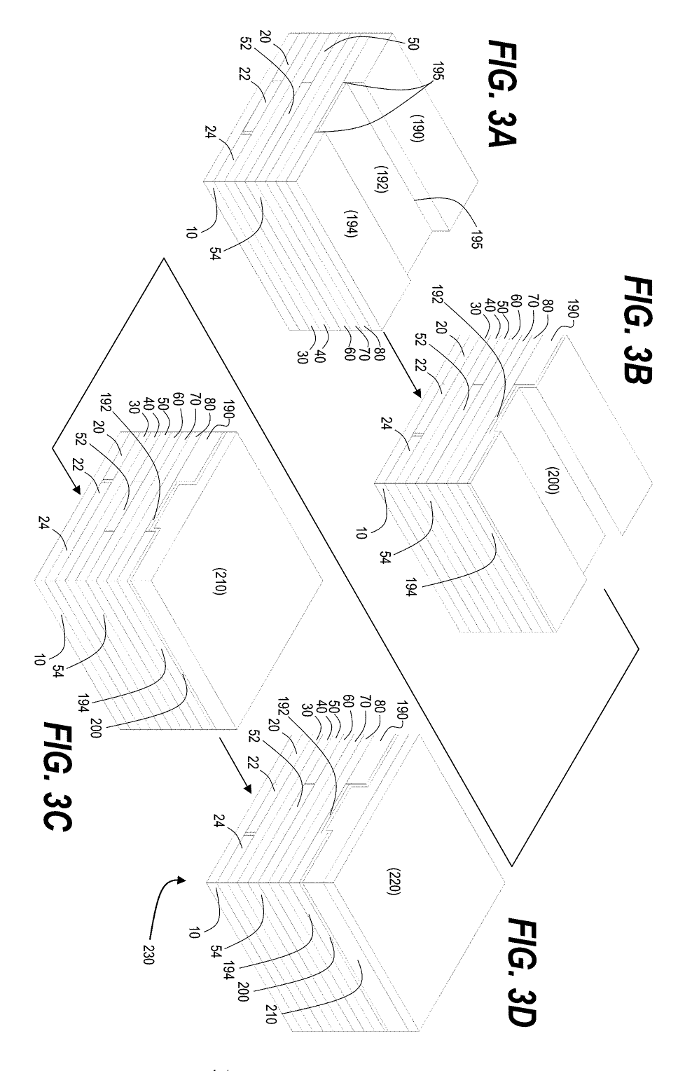

FIG. 1C illustrates a third step in fabrication of a the directly patterned OLED display where an electron transport layer 60, a transparent electrode layer 70 and a thin film encapsulation layer 80 are patterned upon the partial build-up of FIG. 1B. Transparent electrode layer 70 may be an anode or a cathode. Thin film encapsulation layer 80 may be arranged over transparent electrode layer 70 to prevent contamination, by for instance moisture, of RGB emissive layers 50, 52 and 54 or other layers of the sub-pixel. The partial subpixel build-up 1 illustrated in FIG. 1C is the representative starting point for the two embodiments presented hereinafter, where the first embodiment is illustrated by FIGS. 2A-2D, and the second embodiment is illustrated by FIGS. 3A-3D.

FIGS. 2A-2D illustrates a first embodiment of the OLED sub-pixel of the directly patterned OLED display. FIG. 2A particularly illustrates patterning a corresponding red color filter layer 90, a green color filter layer 92, and a blue color filter layer 94 upon the partial subpixel build-up 1 illustrated in FIG. 1C. Particularly, the red color filter layer 90 is disposed above the transparent electrode layer 70 and the red emissive layer 52; the green color filter layer 92 is disposed above the transparent electrode layer 70 and the green emissive layer 52; and, the blue color filter layer 94 is disposed above the transparent electrode layer 70 and the blue emissive layer 54. The RGB color filter layers 90, 92 and 94 may comprise pigment, dye or inorganic material.

In an alternative embodiment, the OLED sub-pixel structure may substitute the above-disclosed top emitter type configuration for a bottom emitter type configuration, (not shown), where a color filter(s), (disclosed below), may be patterned prior to the directly patterning a bottom emitter-type RGB color emissive layers 50, 52 and 54.

FIG. 2A in the first embodiment further graphically illustrates each RGB color filter layer 90, 92 and 94 being substantially the same thickness. Two factors play a major role in the transmissivity of the color filter material used in the RGB color filter layers 90, 92 and 94. First, the chemical and physical compositions of the color filter layers are significant, and second, the thickness of each color filter layer is also significant. The color filter layer thickness is important from a display color saturation standpoint, in that the thicker the color filter layer is, the better the performance of the color filter layer. The RGB color filter layers 90, 92 and 94 may be patterned on top of the respective RBG color emissive layers 50, 52 and 54 array using photolithography, a cover plate with a color filter, or any other equivalent material deposition technique. As discussed below, in some embodiments, thicknesses may different from color filter to color filter on the same sub-pixel.

Opaque separating layers 95 may extend between adjacent peripheral edges of each color filter layer a top edge of a transparent organic layer 100, (see FIG. 2B). Opaque separating layers 95 may function to prevent visible light from one color sub-pixel from leaking into an adjacent pixel and thereby causing the emission of light outside a desired spectrum. Opaque separating layers 95 may be composed of a filter material including all RGB color filter materials in order to obtain an opaque material. Opaque separating layers 95 may be deposited in the same or similar process step as the deposition of RGB color filter layers 90, 92 and 94.

FIG. 2B illustrates patterning a transparent organic layer 100 on the partial build-up of FIG. 2A and over each of the RGB color filter layers 90, 92 and 94. The transparent organic layer 100 may include multilayer organic and/or inorganic material layers.

FIG. 2C illustrates patterning an adhesive layer 110 on the partial build-up of FIG. 2B directly over the transparent organic layer 100.

FIG. 2D illustrates adjoining a cover layer 120 on the partial build-up of FIG. 2C directly over and adjoined to the adhesive layer, thereby illustrating a completed sub-pixel 130 of the first embodiment. Cover layer 120 may be glass layer, and/or may be scratch protection layer, non-reflective layer, or a capacitive touch-screen layer. In an alternative embodiment, an anti-reflective layer (not shown) may be positioned on the back side of cover layer 120 or on the front side of cover layer 120.

FIGS. 3A-3D illustrates a second embodiment of the OLED sub-pixel of the directly patterned OLED display. FIG. 3A particularly illustrates patterning a corresponding red 190, green 192, and blue 194 color filter layer upon the partial subpixel build-up 1 illustrated in FIG. 1C. Particularly, the red color filter layer 190 is disposed above the transparent electrode layer 70 and the red emissive layer 52; the green color filter layer 192 is disposed above the transparent electrode layer 70 and the green emissive layer 52; and, the blue color filter layer 194 is disposed above the transparent electrode layer 70 and the blue emissive layer 54. The RGB color filter layers 190, 192 and 194 may comprise pigment, dye or inorganic material.

FIG. 3A in the second embodiment further graphically illustrates each RGB color filter layer 190, 192 and 194 having a substantially different thickness from each other color filter layer. The thickness of each color filter layer is significant in the second embodiment since the color filter layer thickness is important from a display color tuning standpoint, in that the thickness of each color filter layer may be adjusted to tune or trim a certain range of wavelength emission from the color emission layers. Using the green filter layer 192 as an example, the green filter layer 192 not only blocks red and blue OLED emissive light that may be bleed from adjacent color emissive layers, but the green filter layer 192 may trim a certain portion of the green spectrum emitted by the green emissive layer 52. This trimming via the color filter layers of the individual red, green or blue spectrum emitted by the corresponding color emitter has benefits in both color balancing of the overall OLED display device and increasing the color gamut of each sub-pixel in the OLED display device.

In color balancing, for example, if the green emitter layer 52, without any color filter, has a higher intensity than adjacent red 50 and blue 54 emitter layers without any color filters, then the emitted green light will be stronger than the emitted red and blue light, causing a green shifting in the OLED display when mixing the emitted light of each OLED stack. Color balancing an OLED display requires that the relative transmittance of the three sub-pixels in an RGB OLED display have comparable intensities. In particular, the combination of the light emitted from an RGB display with all three sub-pixels on should be close to a standard white color, for instance point D65 on a 1931 CIE color coordinate graph.

In the second embodiment, a single color filter layer may be deposited to a predetermined thickness to compensate for any unbalanced color emitter layer. If the chemical and physical composition of the color filter layers may be adjusted such that a thickness of a color filter layer may corresponds to a particular degree of emitter intensity attenuation, then individual color emitter layer intensities may be adjusted with the application of a deposited color filter layer having a corresponding thickness.

With respect to increasing the color gamut of each sub-pixel in the OLED display device, the chemical and physical compositions of the color filter layers may be adjusted such that a thickness of a color filter layer may correspond to a particular range of wavelength light allowed to pass through the color filter layer from a wider emission spectrum from the color emitter. In this manner, undesirable wavelengths of light emission may be trimmed from the original emitted light to increase the color gamut of each red, green and blue color sub-pixel.

FIGS. 3A-3D illustrate a representative example of different thicknesses of each RGB color filter layer 190, 192 and 194. However, not all color filter layer need be applied to the intermediate pixel stack illustrated in FIG. 1C. If only one color sub-pixel needs adjustment, for example, in intensity or emission spectrum, then only one color filter layer may be applied at the requisite thickness to the corresponding color sub-pixel and the remainder of the color filter layer is left without any deposited color filter layers. Additionally, if two or more color sub-pixels need adjustment, for example, in intensity or emission spectrum, then only two color or more corresponding filter layers may be applied at the requisite thickness to the corresponding color sub-pixels in the same manner.

In an alternative embodiment, the color filter layers may be comprised of quantum dot material composed of very small semiconductor particles, (typically 2-10 nm in size), that fluoresces light of specific the electromagnetic spectrum frequencies when a current or particular wavelength of light is applied to them. These emitted frequencies can be precisely tuned by changing the quantum dots' size, shape and material. More particularly, when the color emitters excite the quantum dot material, the quantum dots generate a Stokes shift in the quantum dot emitted light capable of achieving more color saturation and a wider color gamut. For example, quantum dotes perform a red-shift of the emitted frequency to a longer wavelength, i.e., a blue wavelength to a green or red wavelength, a green wavelength to a red wavelength, or a red wavelength to a more saturated red wavelength. Quantum dot material may also shift and/or narrow the color spectrum of emitted light.

Opaque separating layers 195 may extend between adjacent peripheral edges of each color filter layer a top edge of a transparent organic layer 200, (see FIG. 3B). Opaque separating layers 195 may function to prevent visible light from one color sub-pixel from leaking into an adjacent pixel and thereby causing the emission of light outside a desired spectrum. Opaque separating layers 195 may be composed of a filter material including all RGB color filter materials in order to obtain an opaque material. Opaque separating layers 195 may be deposited in the same or similar process step as the deposition of RGB color filter layers 190, 192 and 194.

FIG. 3B illustrates patterning a transparent organic layer 200 on the partial build-up of FIG. 3A and over each of the RGB color filter layers 190, 192 and 194. The transparent organic layer 200 may include multilayer organic and/or inorganic material layers. If one or more color sub-pixels does not need the application of any color filter layer for the reasons identified above, the transparent organic layer 200 would be deposited directly on any non-patterned portion of the thin film encapsulation layer 80

FIG. 3C illustrates patterning an adhesive layer 210 on the partial build-up of FIG. 3B directly over the transparent organic layer 200. The adhesive layer 210 is configured to fill in any unevenness in height resulting in differences in thickness of the RGB color filter layers 190, 192 and 194, or resulting in the lack of application of any color filter layer on the thin film encapsulation layer 80 for the reasons identified above.

FIG. 3D illustrates adjoining a cover layer 220 on the partial build-up of FIG. 3C, thereby illustrating a completed sub-pixel 230 of the second embodiment. In an alternative embodiment, an anti-reflective layer (not shown) may be positioned on the back side of cover layer 220 or on the front side of cover layer 220.

The OLED display described herein, in either the first or second embodiments, may be of both active and passive matrix with any dimension of completed sub-pixels 130 or 230. The display may have any type of a back plane including but not limited to silicon or polysilicon wafer, glass backplane coated with conducting film or films, flexible organic and inorganic backplane or a backplane using combination of both. The active or passive matrix OLED color display may be emitting from either positive current electrode side or negative current electrode side or both sides simultaneously.

The active or passive matrix OLED color display may utilize any type of organic material inside its organic stack including but not limited to small molecule OLED materials, polymer OLED materials, carbon nanotube materials, quantum dot type materials and other materials used to produce light in visible optical band by passing electrical current through the stack. The active or passive OLED color display may utilize any organic or inorganic stack configuration including but not limited to single unit OLED devices, multiunit tandem type OLED devices, stacked OLED devices, with any sequence of the transport and light emitting layers. The active or passive OLED color display may emit light in any color in the visible optical band including but not limited to white, red, green, blue, and yellow.

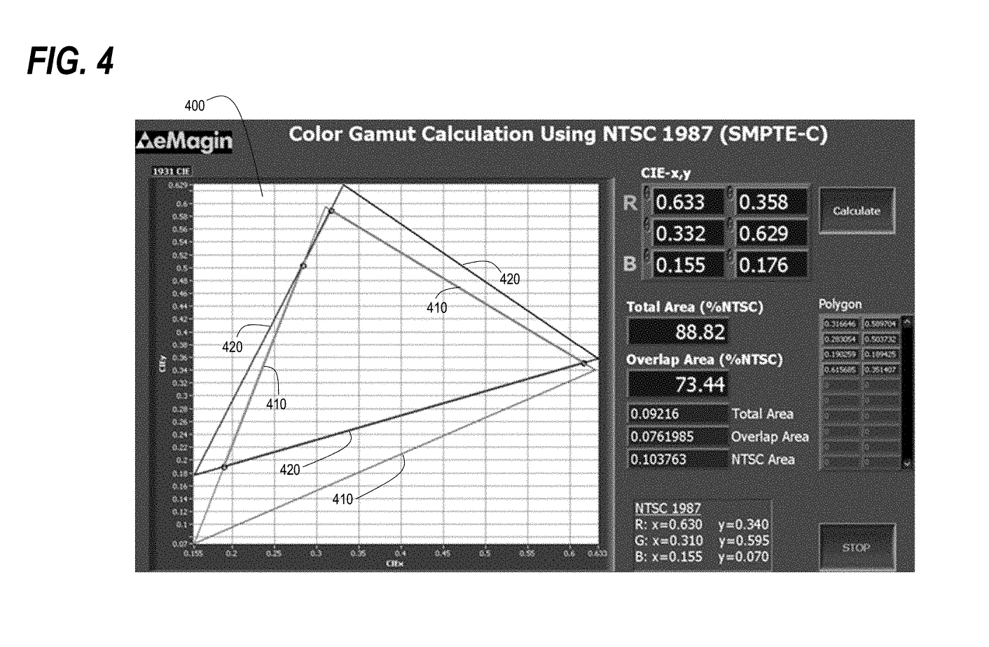

FIG. 4 illustrates an unmodified, (i.e., no color filter layer correction), subpixel color gamut chart 400 using an NTSC 1987 standard gamut color space 410 overlaid with an unmodified sub-pixel gamut color space 420 of a directly patterned OLED display. The unmodified sub-pixel gamut color space 420 encompasses a total area of 88.82% of the NTSC 1987 standard gamut color space 410 and has an overlap area of 73.44% of the NTSC 1987 standard gamut color space 410.

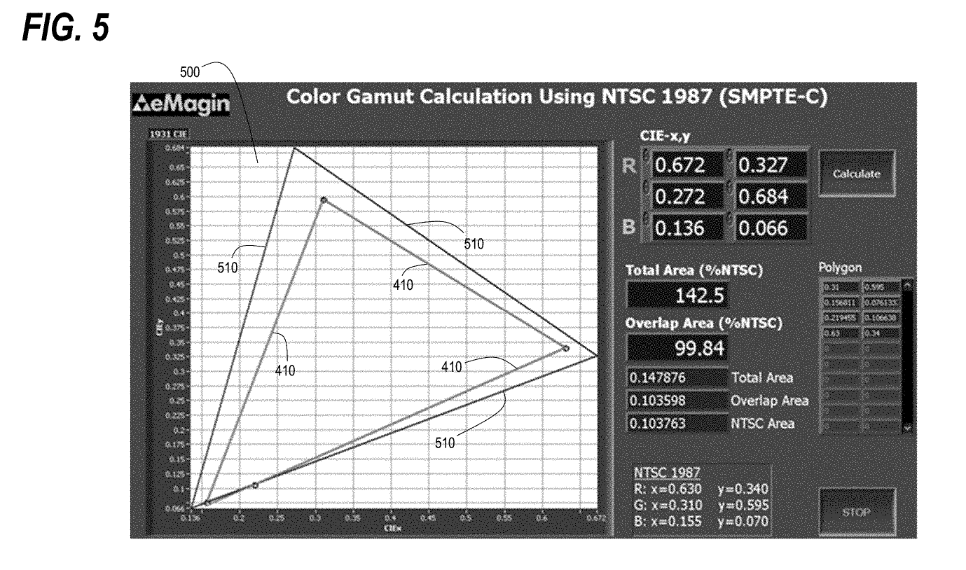

FIG. 5 illustrates a color filter modified color gamut chart 500 using the same NTSC 1987 standard gamut color space 410 but now overlaid with a color filter modified sub-pixel gamut color space 510 of a directly patterned OLED display. The color filter modified sub-pixel gamut color space 510 encompasses a total area of 142.5% of the NTSC 1987 standard gamut color space 410 and has an overlap area of 99.84% of the NTSC 1987 standard gamut color space 410.

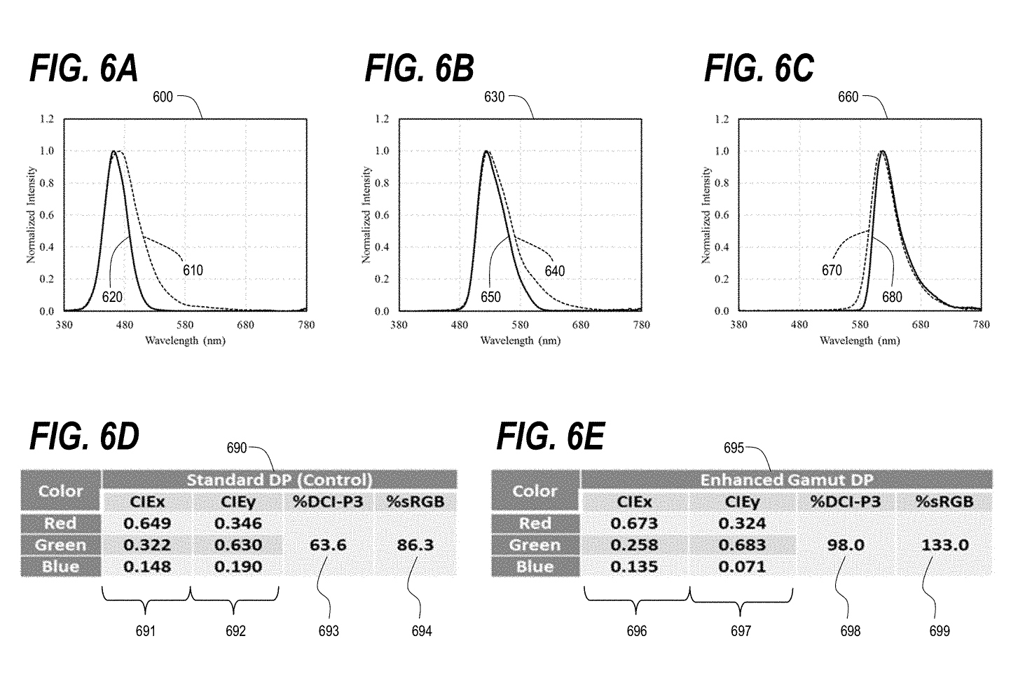

FIG. 6A illustrates a blue wavelength vs. normalized intensity chart 600 depicting an unmodified blue emission spectrum 610 (without any blue color filter layer), and a filtered blue emission spectrum 620 with a blue color filter layer.

FIG. 6B illustrates a green wavelength vs. normalized intensity chart 630 depicting an unmodified green emission spectrum 640 (without any green color filter layer), and a filtered green emission spectrum 650 with a green color filter layer.

FIG. 6C illustrates a red wavelength vs. normalized intensity chart 660 depicting an unmodified red emission spectrum 670 (without any red color filter layer), and a filtered red emission spectrum 680 with a red color filter layer.

FIG. 6D illustrates a standard direction pattern OLED color gamut table 690 displaying color space 1931 CIE-x and 1931 CIE-y coordinates values for unfiltered red, green and blue emission spectrums of a representative sub-pixel RGB. Table 690 shows 1931 CIE-x values 691 for red-x, green-x, and blue-x coordinates, and 1931 CIE-y values 692 for red-y, green-y, and blue-y coordinates. The same unfiltered red, green and blue emission spectrums generate a DCI-P3 color space value 693 of 63.6% based on the following DCI-P3 standard coordinate values:

Rx, Gx, Bx: (0.680, 0.265, 0.150); and

Ry, Gy, By: (0.320; 0.690; 0.060).

The same unfiltered red, green and blue emission spectrums generate a sRGB color space value 694 of 86.3% based on the following sRGB standard coordinate values:

Rx, Gx, Bx: (0.640, 0.300, 0.150); and

Ry, Gy, By: (0.330, 0.600, 0.060).

FIG. 6E illustrates an enhanced, (i.e., color filtered) direct pattern OLED color gamut table 695 showing color space 1931 CIE-x and 1931 CIE-y coordinates values for filtered red, green and blue emission spectrums of a color filter modified sub-pixel. Table 695 shows 1931 CIE-x values 696 for red-x, green-x, and blue-x coordinates, and 1931 CIE-y values 697 for red-y, green-y, and blue-y coordinates. The same filtered red, green and blue emission spectrums generate a DCI-P3 color space value 698 of 98.0% (demonstrating a 54.8% improvement over the unfiltered DCI-P3 value 693 of FIG. 6D), based on the above-identified DCI-P3 coordinate values. The same filtered red, green and blue emission spectrums generate a sRGB color space value 699 of 133.0% (demonstrating a 54.1% improvement over the unfiltered sRGB value of FIG. 6D) based on the above-identified sRGB coordinate values.

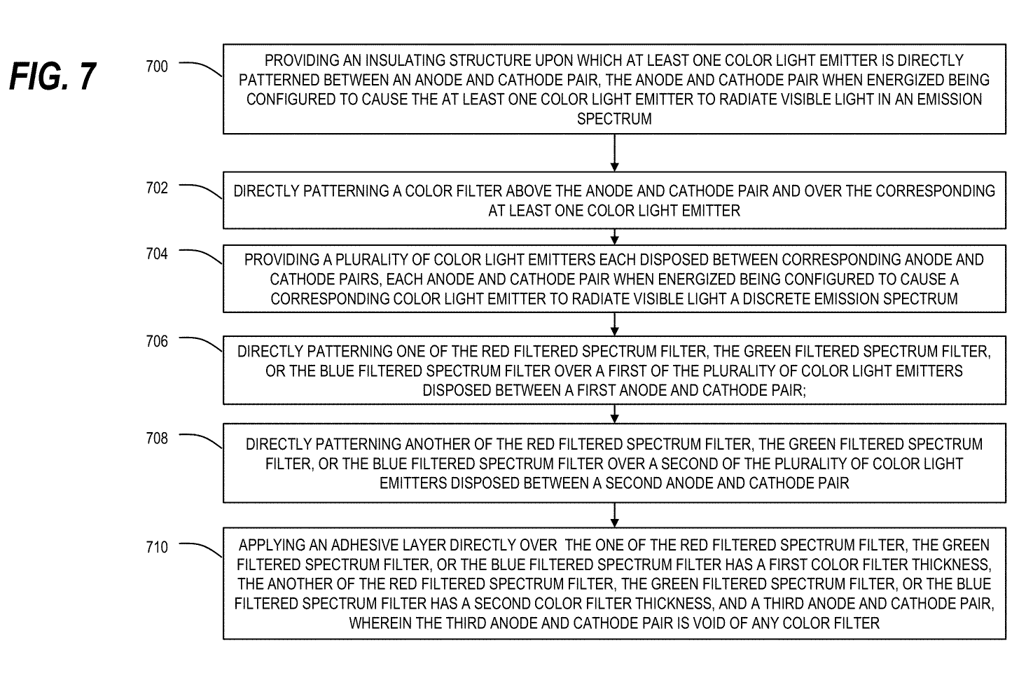

FIG. 7 illustrates a logic flow diagram of a first embodiment of a method of fabricating an OLED sub-pixel. The method includes providing 700 an insulating structure upon which at least one color light emitter is directly patterned between an anode and cathode pair, the anode and cathode pair when energized being configured to cause the at least one color light emitter to radiate visible light in an emission spectrum, and patterning 702 a color filter above the anode and cathode pair and over the corresponding at least one color light emitter. The method further includes providing 704 a plurality of color light emitters each disposed between corresponding anode and cathode pairs, each anode and cathode pair when energized being configured to cause a corresponding color light emitter to radiate visible light a discrete emission spectrum.

The method further includes patterning 706 one of the red filtered spectrum filter, the green filtered spectrum filter, or the blue filtered spectrum filter over a first of the plurality of color light emitters disposed between a first anode and cathode pair, and patterning 708 another of the red filtered spectrum filter, the green filtered spectrum filter, or the blue filtered spectrum filter over a second of the plurality of color light emitters disposed between a second anode and cathode pair.

The method further includes applying 710 an adhesive layer directly over the one of the red filtered spectrum filter, the green filtered spectrum filter, or the blue filtered spectrum filter has a first color filter thickness, the another of the red filtered spectrum filter, the green filtered spectrum filter, or the blue filtered spectrum filter has a second color filter thickness, and a third anode and cathode pair, wherein the third anode and cathode pair is void of any color filter.

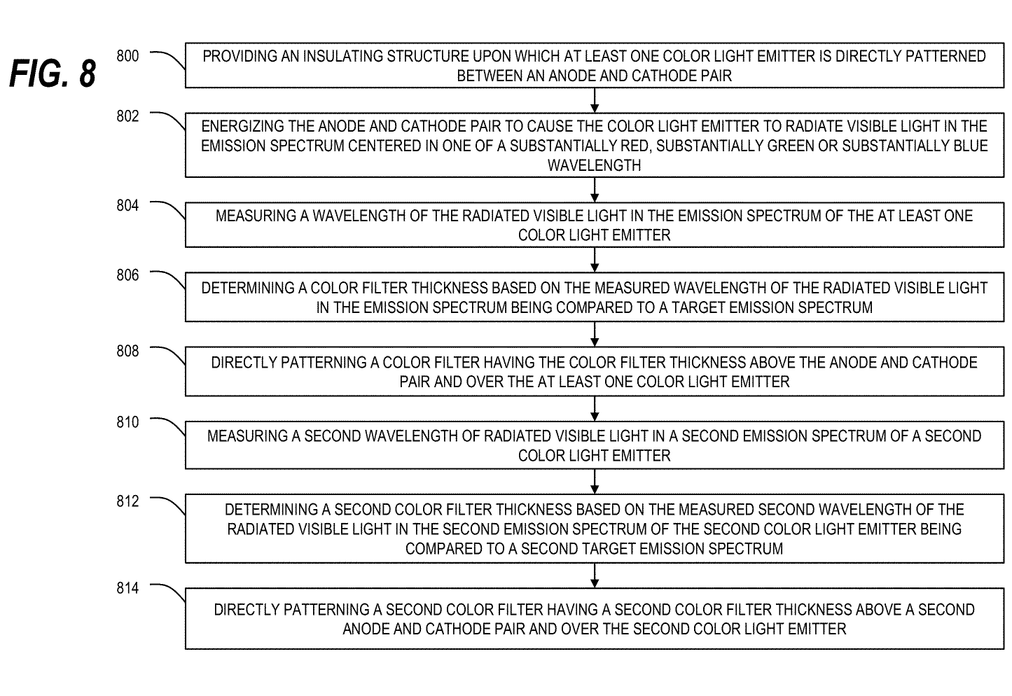

FIG. 8 illustrates a logic flow diagram of a second embodiment of a method of fabricating an OLED sub-pixel. The method includes providing 800 an insulating structure upon which at least one color light emitter is directly patterned between an anode and cathode pair, and energizing 810 the anode and cathode pair to cause the color light emitter to radiate visible light in the emission spectrum centered in one of a substantially red, substantially green or substantially blue wavelength.

The method further includes measuring 804 a wavelength of the radiated visible light in the emission spectrum of the at least one color light emitter, and determining 806 a color filter thickness based on the measured wavelength of the radiated visible light in the emission spectrum being compared to a target emission spectrum. The method further includes patterning 808 a color filter having the color filter thickness above the anode and cathode pair and over the at least one color light emitter, and measuring 810 a second wavelength of radiated visible light in a second emission spectrum of a second color light emitter.

The method further includes determining 812 a second color filter thickness based on the measured second wavelength of the radiated visible light in the second emission spectrum of the second color light emitter being compared to a second target emission spectrum, and patterning 814 a second color filter having a second color filter thickness above a second anode and cathode pair and over the second color light emitter.

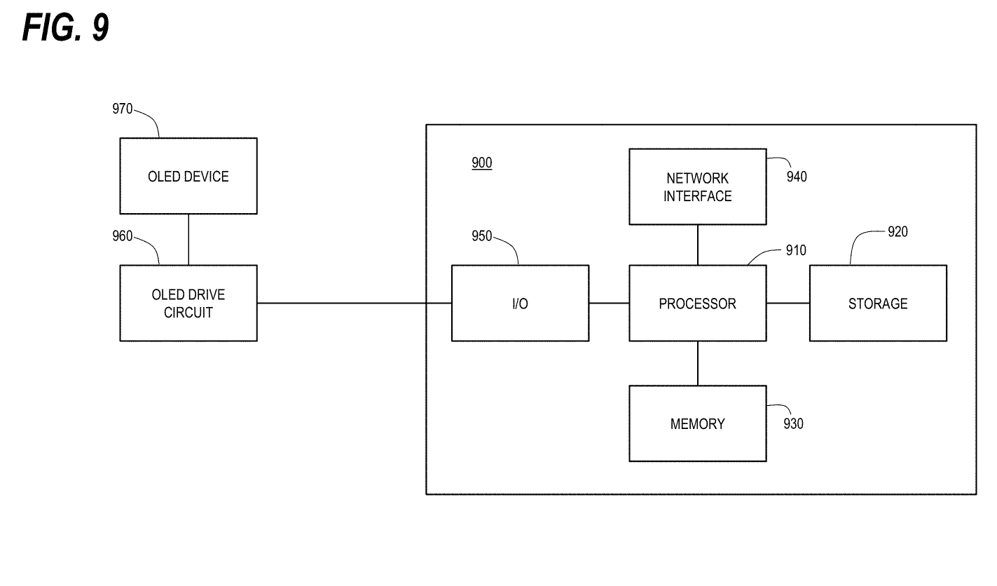

FIG. 9 illustrates a computer system according to an exemplary embodiment configured to drive an OLED array using the directly patterned OLED display comprised of the completed color filtered sub-pixels 130 and 230 depicted in FIG. 2D and FIG. 3D. Computer 900 can, for example, operate OLED driver circuit 960 that controls and OLED device 970 comprised of a plurality of the completed OLED sub-pixels of the first embodiment 130 or the completed OLED sub-pixels of the second embodiment 230.

High resolution active matrix displays may include millions of pixels and sub-pixels that are individually addressed by the OLED drive circuit 960. Each sub-pixel can have several semiconductor transistors and other IC components. Each OLED may correspond to a pixel or a sub-pixel, and these terms are used interchangeably herein.

Additionally, computer 900 can perform the steps described above (e.g., with respect to FIG. 4). Computer 900 contains processor 910 which controls the operation of computer 900 by executing computer program instructions which define such operation, and which may be stored on a computer-readable recording medium. The computer program instructions may be stored in storage 920 (e.g., a magnetic disk, a database) and loaded into memory 930 when execution of the computer program instructions is desired. Thus, the computer operation will be defined by computer program instructions stored in memory 930 and/or storage 920 and computer 900 will be controlled by processor 910 executing the computer program instructions. Computer 900 also includes one or more network interfaces 940 for communicating with other devices, for example other computers, servers, or websites. Network interface 940 may, for example, be a local network, a wireless network, an intranet, or the Internet. Computer 900 also includes input/output 950, which represents devices which allow for user interaction with the computer 900 (e.g., display, keyboard, mouse, speakers, buttons, webcams, etc.). One skilled in the art will recognize that an implementation of an actual computer will contain other components as well, and that FIG. 9 is a high-level representation of some of the components of such a computer for illustrative purposes.

In summary, the inclusion of a color filter layer matching a corresponding color emitter layer has several benefits, namely, the resultant emission spectrum may be more saturated, and the color gamut significantly increased to meet improve device gamut specifications; any undesired portion of the emissive spectrum may be filtered out. Since the color filter layer matches the color of the OLED layer, the emissive light lost is minimized. For example, only non-green light will be filtered from the green pixel, so the bulk of the light is transmitted by the color filter layer lessens any color intensity attenuation by the color filter layer. Further, the thickness of the color filter can be optimized to tune the emissive spectrum color performance which allows a great degree of control over color gamut performance of the OLED device. Additionally, not all color subpixels need to receive a color filter layer, that is, for example, if the performance for two colors is adequate but only one color needs improvement, then only one color in the color filter layer may be applied.

While only a limited number of preferred embodiments have been disclosed for purposes of illustration, it is obvious that many modifications and variations could be made thereto. This disclosure intends to cover all of those modifications and variations which fall within the scope of the present invention, as defined by the following claims.

What is claimed is:

1. A method of fabricating an Organic Light Emitting Diode (OLED) sub-pixel comprising:
providing an insulating structure upon which at least one color light emitter is directly patterned between an anode and cathode pair, the anode and cathode pair when energized being configured to cause the at least one color light emitter to radiate visible light in an emission spectrum; and
patterning a color filter above the anode and cathode pair and over the corresponding at least one color light emitter,
wherein the radiated visible light in the emission spectrum from the at least one color light emitter is configured to pass through the color filter and radiate visible light in a filtered spectrum, the radiated visible light in the filtered spectrum being narrower in wavelength than radiated visible light in the emission spectrum.

2. The method of fabricating the OLED sub-pixel according to claim 1, further comprising:
applying an adhesive layer directly over the color filter above the anode and cathode pair and over the corresponding at least one color light emitter, and over second and third anode and cathode pairs of the OLED sub-pixel,
wherein the second and third anode and cathode pairs are void of any patterned color filter.

3. The method of fabricating the OLED sub-pixel according to claim 1, further comprising:
providing a plurality of color light emitters each disposed between corresponding anode and cathode pairs, each anode and cathode pair when energized being configured to cause a corresponding color light emitter to radiate visible light a discrete emission spectrum; and
wherein the radiated visible light particular in the emission spectrum from each of the plurality of color light emitters is configured to pass through a discrete color filter and radiate visible light in a discrete filtered spectrum.

4. The method of fabricating the OLED sub-pixel according to claim 3, wherein each the plurality of color light emitters comprises one of:
a substantially red emission spectrum emitter centered on a substantially red wavelength;
a substantially green emission spectrum emitter centered on a substantially green wavelength; or
a substantially blue emission spectrum emitter centered on a substantially blue wavelength,
wherein each corresponding color filter for the plurality of color light emitters comprises one of:
a red filtered spectrum filter centered on the substantially red wavelength;
a green filtered spectrum color filter centered on the substantially green wavelength; and
a blue filtered spectrum color filter centered on the substantially blue wavelength.

5. The method of fabricating the OLED sub-pixel according to claim 4, wherein patterning the color filter above the anode and cathode pair and over the corresponding at least one color light emitter further comprises:
patterning one of the red filtered spectrum filter, the green filtered spectrum filter, or the blue filtered spectrum filter over a first of the plurality of color light emitters disposed between a first anode and cathode pair;
patterning another of the red filtered spectrum filter, the green filtered spectrum filter, or the blue filtered spectrum filter over a second of the plurality of color light emitters disposed between a second anode and cathode pair.

6. The method of fabricating the OLED sub-pixel according to claim 5, wherein the one of the red filtered spectrum filter, the green filtered spectrum filter, or the blue filtered spectrum filter has a first color filter thickness,
wherein the another of the red filtered spectrum filter, the green filtered spectrum filter, or the blue filtered spectrum filter has a second color filter thickness, and
wherein the first color filter thickness being substantially different than the second color filter thickness.

7. The method of fabricating the OLED sub-pixel according to claim 5, further comprising:
applying an adhesive layer directly over
the one of the red filtered spectrum filter, the green filtered spectrum filter, or the blue filtered spectrum filter has a first color filter thickness,
the another of the red filtered spectrum filter, the green filtered spectrum filter, or the blue filtered spectrum filter has a second color filter thickness, and
a third anode and cathode pair, wherein the third anode and cathode pair is void of any color filter.

8. The method of fabricating the OLED sub-pixel according to claim 4, wherein patterning the color filter above the anode and cathode pair and over the corresponding at least one color light emitter further comprises:
patterning the red filtered spectrum filter over the substantially red emission spectrum emitter;
patterning the green filtered spectrum filter over the substantially green emission spectrum emitter; and
patterning the blue filtered spectrum filter over the substantially blue emission spectrum emitter.

9. The method of fabricating the OLED sub-pixel according to claim 8, wherein at least two of the red filtered spectrum filter, the green filtered spectrum filter, and the blue filtered spectrum filter comprises substantially different thicknesses.

10. The method of fabricating the OLED sub-pixel according to claim 9, further comprising:
applying an adhesive layer directly over the red filtered spectrum color filter, the green filtered spectrum color filter, and the blue filtered spectrum color filter;
adhering a transparent protective layer via the adhesive layer,
wherein the adhesive layer accommodates for differences in thicknesses of the at least two of the red filtered spectrum color filter, the green filtered spectrum color and the blue filtered spectrum color filter with respect to adjacent anode and cathode pairs.

11. An Organic Light Emitting Diode (OLED) device comprising:
a plurality of sub-pixels arranged in an array, each of the plurality of sub-pixels including:
an insulating structure upon which a plurality of color light emitters are patterned between corresponding anode and cathode pairs, the anode and cathode pairs when energized being configured to cause each corresponding color light emitter to radiate visible light in one of a red, green or blue emissive spectrum; and
at least one color filter disposed above at least one of the anode and cathode pairs and over at least one of the corresponding plurality of color light emitters, wherein the radiated visible in one of the red, green or blue emissive spectrum from the plurality of color light emitters is configured to pass through the at least one color filter and radiate visible light in a corresponding narrowed red, green or blue filtered spectrum; and
a controller configured to address each of plurality of sub-pixels in the array and configured to control the energizing of each anode and cathode pair to cause a corresponding color light emitter to radiate visible light in one of a red, green or blue emissive spectrum.

12. The OLED device according to claim 11, further comprising:
an adhesive layer disposed over the at least one color filter; and
a transparent protective layer disposed over the plurality of sub-pixels arranged in the array,
wherein the adhesive layer accommodates for differences in total thicknesses of sub-pixels with respect to adjacent anode and cathode pairs between the anode and cathode pairs and the transparent protective layer.

13. The OLED device according to claim 11, further comprising at least two color filters disposed above at least two corresponding anode and cathode pairs and over at least two corresponding plurality of color light emitters,
wherein the radiated emissive spectrum from each of the at least two corresponding plurality of color light emitters is configured to pass through the corresponding at least two color filters and radiate visible light in a corresponding narrowed red, green or blue filtered spectrum.

14. The OLED device according to claim 13, wherein at least two color filters comprises substantially different thicknesses.

15. The OLED device according to claim 11, further comprising:
a red color filter disposed above a first corresponding anode and cathode pair and over a red emission spectrum light emitter configured to emit a corresponding narrowed red filtered spectrum;
a green color filter disposed above a second corresponding anode and cathode pair and over a green emission spectrum light emitter configured to emit a corresponding narrowed green filtered spectrum; and
a blue color filter disposed above a third corresponding anode and cathode pair and over a blue emission spectrum light emitter configured to emit a corresponding narrowed blue filtered spectrum.

16. The OLED device according to claim 15, wherein at least two of the red color filter, the green color filter, and the blue color filter comprises substantially different thicknesses.

17. The OLED device according to claim 11, wherein each of the plurality of color light emitters pixels is less than or equal to 15 microns in size.

18. The OLED device according to claim 11, wherein the at least one color filter comprises a fluorescing quantum dot material.

19. A method of fabricating an Organic Light Emitting Diode (OLED) sub-pixel comprising:
providing an insulating structure upon which at least one color light emitter is directly patterned between an anode and cathode pair;
energizing the anode and cathode pair to cause the color light emitter to radiate visible light in the emission spectrum centered in one of a substantially red, substantially green or substantially blue wavelength;
measuring a wavelength of the radiated visible light in the emission spectrum of the at least one color light emitter;
determining a color filter thickness based on the measured wavelength of the radiated visible light in the emission spectrum being compared to a target emission spectrum; and
patterning a color filter having the color filter thickness above the anode and cathode pair and over the at least one color light emitter;
wherein the color filter is configured to cause the visible light in the emission spectrum to radiate visible light in a filtered spectrum, the filtered spectrum being narrower in wavelength than the emission spectrum and being calibrated to a predetermined color gamut value based on the color filter thickness.

20. The method of fabricating the OLED sub-pixel according to claim 19, further comprising:
measuring a second wavelength of radiated visible light in a second emission spectrum of a second color light emitter;
determining a second color filter thickness based on the measured second wavelength of the radiated visible light in the second emission spectrum of the second color light emitter being compared to a second target emission spectrum; and
patterning a second color filter having a second color filter thickness above a second anode and cathode pair and over the second color light emitter,
wherein the second color filter is configured to cause the visible light in the emission spectrum of the second color light emitter to radiate visible light in a second filtered spectrum, the second filtered spectrum being narrower in wavelength than the emission spectrum of the second color light emitter and being calibrated to a second predetermined color gamut value based on the second color filter thickness.

21. The method of fabricating the OLED sub-pixel according to claim 19, further comprising:
measuring a third wavelength of radiated visible light in third emission spectrum of a third color light emitter;
determining a third color filter thickness based on the measured third wavelength of the radiated visible light in the third emission spectrum of the third color light emitter being compared to a third target emission spectrum; and
patterning a third color filter having a third color filter thickness above a third anode and cathode pair and over the third color light emitter,
wherein the third color filter is configured to cause the visible light in the emission spectrum of the third color light emitter to radiate visible light in a third filtered spectrum, the third filtered spectrum being narrower in wavelength than the emission spectrum of the third color light emitter and being calibrated to a third predetermined color gamut value based on the third color filter thickness.
